(19) United States
(12) Patent Application Publication
(10) Pub. No.: US 2015/0162441 A1
(43) Pub. Date: Jun. 11, 2015

(54) LDMOS DEVICE WITH IMPROVED AVALANCHE ENERGY AND ASSOCIATED FABRICATING METHOD

(71) Applicant: Monolithic Power Systems, Inc., San Jose, CA (US)

(72) Inventors: Joel M. McGregor, San Jose, CA (US); Jeesung Jung, San Jose, CA (US); Eric K. Braun, Mountain View, CA (US); Ji-Hyoung Yoo, Cupertino, CA (US)

(21) Appl. No.: 14/622,686

(22) Filed: Feb. 13, 2015

Related U.S. Application Data
(62) Division of application No. 13/931,700, filed on Jun. 28, 2013.

(51) Int. Cl. H01L 29/78; H01L 29/49; H01L 29/08; H01L 29/167; H01L 21/265; H01L 29/10; H01L 29/66; H01L 29/51

(52) U.S. Cl. CPC H01L 29/7816; H01L 29/7835; H01L 29/66659; H01L 29/66681; H01L 29/4916; H01L 29/51; H01L 29/167; H01L 21/265; H01L 29/1095; H01L 29/0878; H01L 29/086

(57) ABSTRACT

A semiconductor device has: a gate region having a dielectric layer and a conducting layer; an N-type drain region having a lightly doped drift region and a highly doped drain contact region formed in the drift region, wherein the drain region is at a first side of the gate region; a P-type body region adjacent to the drain region, the body region having a lightly doped first portion body region, a second portion body region, and a highly doped body contact region; and an N-type highly doped source region in the body region, wherein the source region is at a second side of the gate region; wherein the first portion body region is doped with boron, the second portion body region is doped with boron and indium in the first portion body region, and the second portion body region is located adjacent to and beneath the source region.

### CROSS REFERENCE TO RELATED APPLICATION

This application is a division of U.S. patent application Ser. No. 13/931,700, filed Jun. 28, 2013 and titled LDMOS DEVICE WITH IMPROVED AVALANCHE ENERGY AND ASSOCIATED FABRICATING METHOD, the contents of which is incorporated by reference in its entirety.

### TECHNICAL FIELD

The present invention generally relates to semiconductor device, and more particular but not exclusively relates to LDMOS device and method of improving the avalanche energy.

### BACKGROUND

FIG. 1 shows a cross-sectional view of a prior art Lateral Diffused Metal-Oxide-Semiconductor Field Effect Transistor (LDMOS) device 100. The LDMOS device 100 comprises a drain having a drift region 112 and a drain contact region 111, a source 12, a body comprising a body region 131 and a body contact region 132, and a gate 14. During normal operation, voltages are applied to the gate 14 and the drain, and the voltage at the gate 14 converts the channel region beneath the gate 14 into the same conductivity type as the drain and the source 12, and accordingly current flows between the drain and the source 12. When the voltage applied at the drain is too high and exceeds the breakdown voltage of the LDMOS device 100, electron-hole pairs are created in high impact ionization area(s) in the drift region 112. Electrons with negative electrical charge go to the highest potential to the N+ drain contact 111 and holes with positive electrical charge go to the lowest potential to the P+ body contact 132. This avalanche breakdown is not destructive, and the LDMOS device 100 may come back to normal when the high voltage is removed.

However, there exists a parasitic NPN bipolar transistor 15 as part of the LDMOS device 100, with the source 12 being the emitter, a portion of the body being the base, and the drain being the collector. When the voltage drop caused by the holes with positive electrical charge traversing along the body region to P+ body contact 132 is high enough, this parasitic NPN bipolar transistor 15 is forward-biased and turned on. Once the NPN transistor 15 is activated in only one spot along the width of the LDMOS device 100, it will quickly get hotter, the current gain (beta) will increase, and the silicon will melt. This destruction is not recoverable.

Thus, it is required that a LDMOS device sinks as much avalanche current as possible before the parasitic bipolar transistor turns on.

At present, some approaches to increase avalanche energy include adopting longer channel and longer drift region. But these approaches lead to bigger devices and therefore have higher cost.

Accordingly, an improved LDMOS device which overcomes some or all of the above deficiencies are required.

### SUMMARY

One embodiment of the present invention discloses a semiconductor device comprising: a gate region comprising a dielectric layer and an electrical conducting layer; an N-type drain region comprising a lightly doped drift region and a highly doped drain contact region formed in the drift region, wherein the drain region is at a first side of the gate region; a P-type body region adjacent to the drain region, the body region comprising a lightly doped first portion body region, a second portion body region adjacent to the first portion body region, and a highly doped body contact region: and an N-type highly doped source region in the body region, wherein the source region is at a second side of the gate region; wherein the first portion body region is doped with boron, the second portion body region is doped with boron and indium, and the second portion body region is located adjacent to and beneath the source region.

### BRIEF DESCRIPTION OF THE DRAWINGS

Non-limiting and non-exhaustive embodiments are described with reference to the following drawings. The drawings are only for illustration purpose. Usually, the drawings only show part of the system or circuit of the embodiments. These drawings are not necessarily drawn to scale. Likewise, the relative sizes of the elements illustrated by the drawings may differ from the relative size depicted.

FIG. 1 shows a cross-sectional view of a prior art LDMOS device 100.

FIG. 2 illustrates a semiconductor device 200 of a LDMOS device according to an embodiment of the present invention.

FIG. 3 shows a LDMOS device 300 in process to illustrate a method of fabricating a LDMOS device according to an embodiment of the present invention.

FIGS. 4A-4H illustrate a process flow of fabricating a LDMOS device according to an embodiment of the present invention.

FIG. 5 illustrates a sectional view of a semiconductor device 500 of LDMOS device where indium atoms are implanted extending past the source region according to an embodiment of the present invention.

The use of the same reference label in different drawings indicates the same or like components.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

According to some embodiments of the present invention, indium atoms are implanted in a body region of a LDMOS device beneath a source region. Accordingly, the avalanche current sunk by the LDMOS device before a parasitic bipolar transistor turns on is increased.

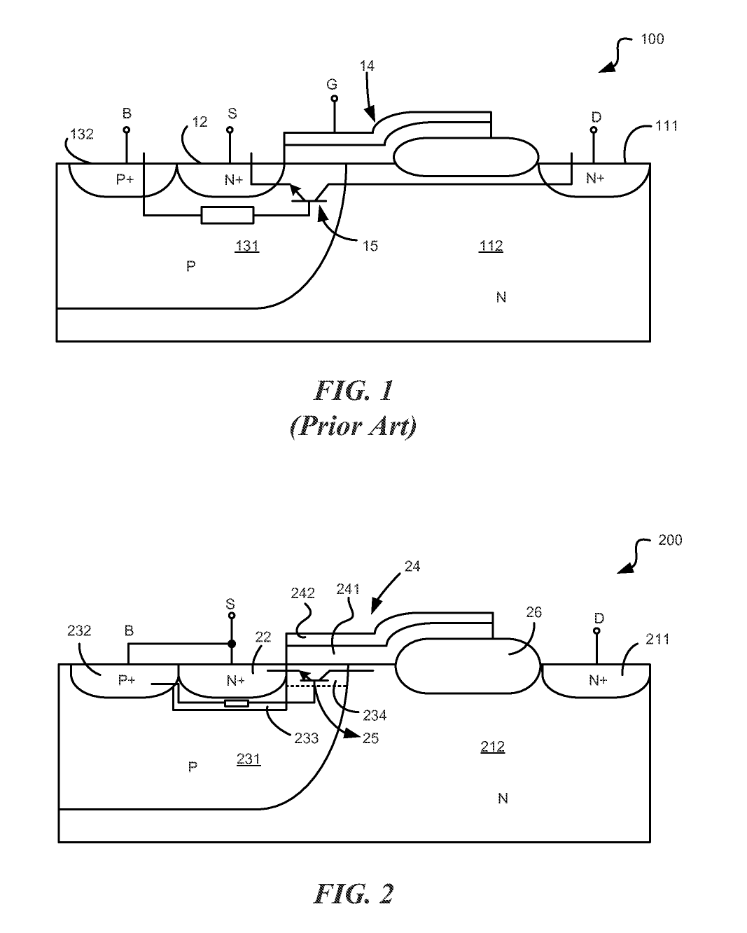

FIG. 2 illustrates a semiconductor device of LDMOS device 200, according to an embodiment of the present invention. The LDMOS device 200 comprises a gate region 24, an N-type drain region, a P-type body region and a highly doped N-type source region 22. The gate region 24 comprises a dielectric layer 241 and an electrical conducting layer 242. In one embodiment, the dielectric layer 241 comprises a silicon dioxide (SiO2) layer, and the conducting layer 242 comprises a polycrystalline silicon layer. The drain region is at the right side of the gate region 24 as shown and comprises a lightly doped drift region 212 and a highly doped drain contact region 211 formed in the drift region 212. The words of “lightly doped” and “highly doped” are not meant to confine the doping concentration for the regions, but only for illustration that the doping concentration for one region such as region 211 is higher than that for another region such as drift region 212. In one embodiment, “highly doped” and “lightly doped” for each doping type, e.g. N-type or P-type in one device may refer to a predetermined doping level, for example, all the highly doped N-type doping regions have the same doping concentration, and all the lightly doped N-type doping regions have a same doping concentration that is lower than that of the highly doped regions. However, “lightly doped” or “highly doped” are not restricted to a predetermined doping level. And the phrases of “right side” or “left side” are only for illustration with reference to the shown embodiment, and it is noted that these positional phrases are changeable from different directions of view.

Continuing with FIG. 2, from the sectional view of FIG. 2, the drift region 212 is located between a body region 231 and the drain contact region 211 laterally, and the drain contact region 211 is coupled to a drain electrode D. An electrode may comprise a metal interconnect, a metal layer or a metal lead of a package, etc. The body region of the LDMOS device 200 comprises a first portion body region 231, a second portion body region 233 adjacent to and formed in the first portion body region 231, and a highly doped body contact region 232, wherein the first portion body region 231 and the body contact region 232 are doped with P-type substance of boron, and the second portion body region 233 is doped with P-type substances of both boron and indium. The second portion body region 233 is located adjacent to and beneath the source region 22. In one embodiment, the doping concentration of indium in the second portion body region 233 is 1-3 times of the doping concentration of boron in the first portion body region 231 and the second portion body region 233. In the shown embodiment, the second portion body region 233 is self-aligned to the gate region 24 of the LDMOS device 200. However in some embodiments, the second portion body region 233 is not self-aligned to the edge of the gate region 24. The body contact region 232 is coupled together with the source region 22 to a source electrode S. In another embodiment, the body contact region 232 may be coupled to a respective body electrode B. The gate 24 of the LDMOS device 200 is formed on part of the body region and drift region 212. And the portion of the body region beneath the gate region 24 forms the channel 234 for the LDMOS device 200. The N-type highly doped source region 22 of the LDMOS device 200 is formed in the body region and is at the left side of the gate region 24 in the shown embodiment in FIG. 2. In the shown embodiment, an optional thick oxide layer 26 which is thicker than the gate oxide 241 is formed between the gate 24 and the drain contact region 211 for a higher breakdown voltage.

FIG. 2 also shows a parasitic NPN bipolar transistor 25 wherein the source region 22 of the LDMOS device 200 functions as the emitter of the parasitic NPN transistor 25, the drain drift region 212 of the LDMOS device 200 functions as the collector of the parasitic transistor 25, and a portion of the body region of the LDMOS device 200 functions as the base of the parasitic transistor 25.

When voltage applied on the drain electrode D is too high, hole-electron pairs are generated, and holes with positive electrical charge collect to the body contact region 232. If this avalanche current is high enough, the voltage drop caused by holes traversing the body region 231 to the body contact 232 will be high enough to forward-bias the source/body junction, and the parasitic NPN transistor 25 turns on. The positive temperature coefficient of NPN current gain creates positive feedback and destruction of the device.

However, since the path under the source 22 from the channel region 234 of the body to the body contact region 232 is additionally doped with indium, the body resistance is decreased. In one embodiment, the doping concentration of indium atoms is in the range of 1×10¹⁸ atoms per cm³to 5×10¹⁸ atoms per cm³, and the doping thickness of indium atoms is in the range of 0.08 to 0.2 times of the thickness of the body region. In one embodiment, the doping concentration of indium atoms is about 5×10¹⁸ atoms per cm³, and the thickness of doped indium atoms is about 100 nm. The reduced body resistance under the N+ source region 22 increases the amount of avalanche current needed to trigger ON the NPN transistor 25. Also, the indium atoms reduce the current gain of the parasitic NPN transistor. This increases the avalanche current at which the destructive positive feedback occurs. In fact, if current gain is less than unity under all conditions, the destructive positive feedback will never occur. Indium implantation reduces the parasitic NPN current gain because indium is a heavy ion. For a given implanted dose and energy, more damage is created in the silicon lattice than a lighter ion, e.g. boron, would create. This damage helps reduce the current gain (beta) of the parasitic NPN bipolar transistor 25. For example, in one experiment, the peak current gain of a parasitic NPN transistor is approximately 50 with a boron-only body, and the peak current gain of the parasitic NPN transistor is reduced to approximately unity (1.0) with a body doped with both boron and indium.

Indium is a deep acceptor impurity. Its ionization energy is approximately 140 meV, compared to approximately 40 meV for boron. Accordingly, indium atoms has less effect on the free hole concentration than boron atoms do. Thus, boron implantation is required along with indium to ensure low body resistance. And in one embodiment, in the first portion body region 233, the doping concentration of indium is 1-3 time of the doping concentration of boron.

In one embodiment, when comparing a LDMOS device which has additional implanted indium at the junction of the body and the source to a LDMOS device without indium, the maximum avalanche current before destruction is increased by a factor of two to ten. Thus the reliability of the LDMOS device is improved.

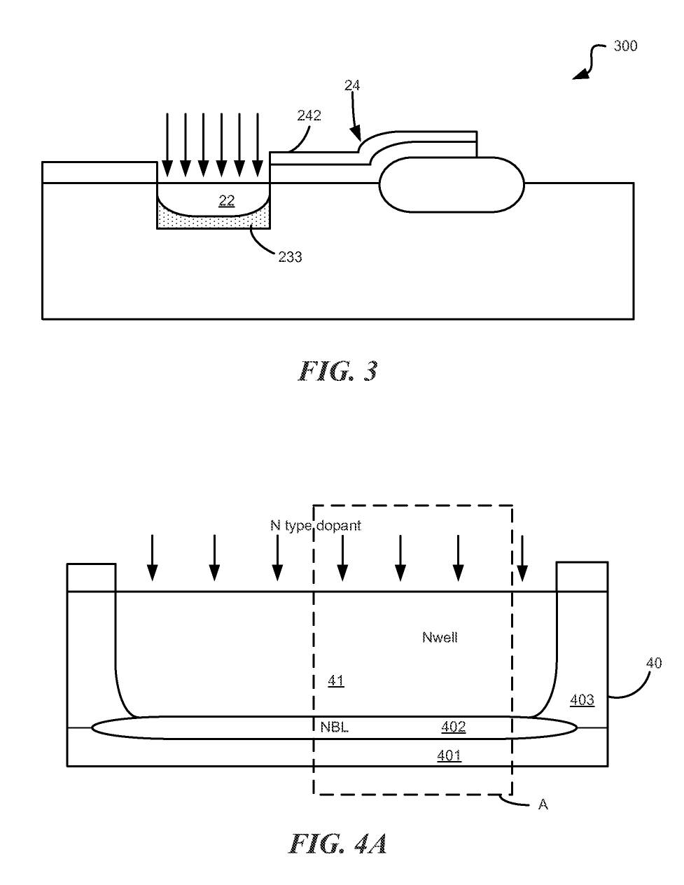

FIG. 3 shows a LDMOS device 300 in process to illustrate a method of fabricating a LDMOS device according to an embodiment of the present invention. After forming a gate region 24 of the LDMOS device 300, indium atoms are implanted into a second portion body region 233 under a source region 22 at the junction area of the source region 22 and the body region. Indium atoms are implanted in addition to boron implantation for forming the body region of the LDMOS device 300. In the shown embodiment, the indium atoms are implanted with zero tilt such that the indium atoms are implanted self-aligned to the edge of the gate region 24. The energy of the indium is selected such that the implanted depth and range is dose to the junction between the N-type source 22 and the P-type body region, and further the energy of indium atoms is low enough so that the gate poly 242 of the gate region 24 blocks the indium atoms from implanting into and penetrating the gate region 24. After implantation, indium atoms are concentrated beneath the source region 22. Indium is a P-type impurity, thus the body resistance between the channel region and body contact region is decreased and the voltage required for “punch-through” between the drain and source is increased.

The diffusivity of indium atoms is much lower than that of other P-type dopants in silicon. Therefore, the indium atoms will remain in the region immediately beneath the source region. If the dense P-type dopants were to diffuse up to the silicon surface, the threshold voltage of the LDMOS device would be increased.

The other regions such as the drain region, first portion body region, body contact region of the LDMOS device 300 are not shown. The other regions may be formed before implanting the indium atoms, or formed after implanting the indium atoms. For example the boron implantation may be performed before implanting the indium atoms, or performed after implanting the indium atoms, according to the different processes or considerations.

The shape of the second portion body region 233 with bottom-side right-angle is only for illustration. As can be appreciated, the shape for the second portion body region where indium atoms are implanted may have different shapes, for example with bottom-side round angle.

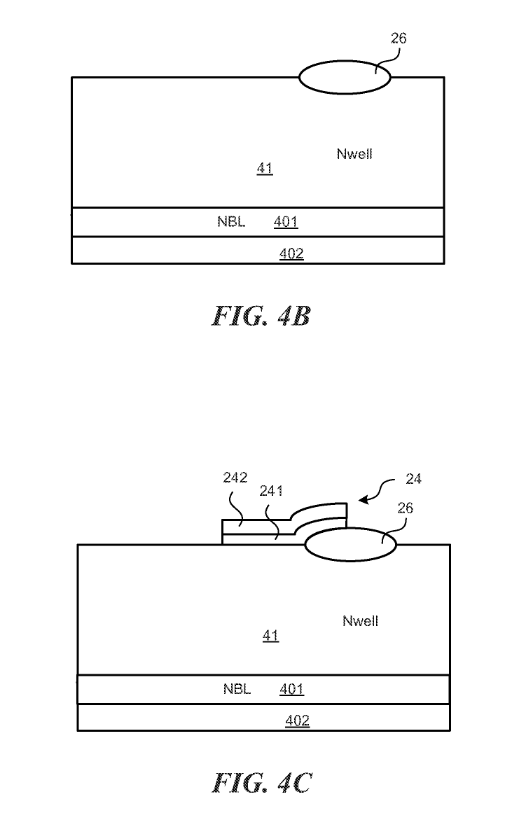

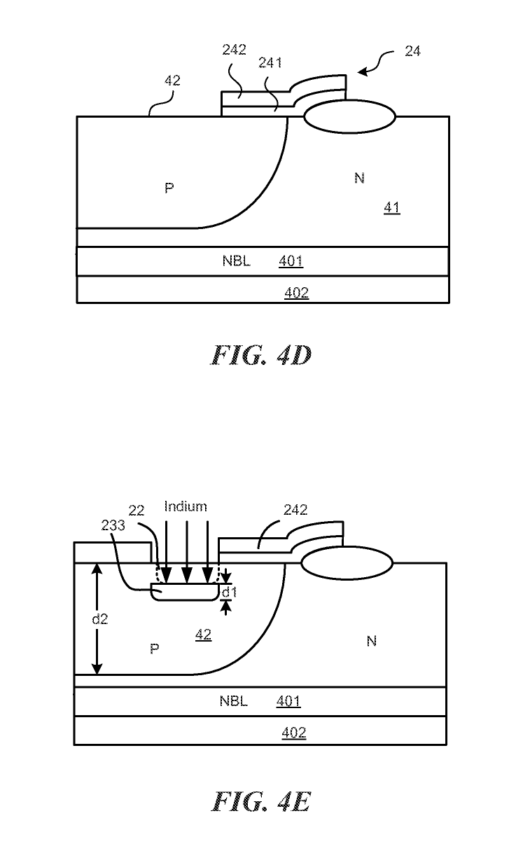

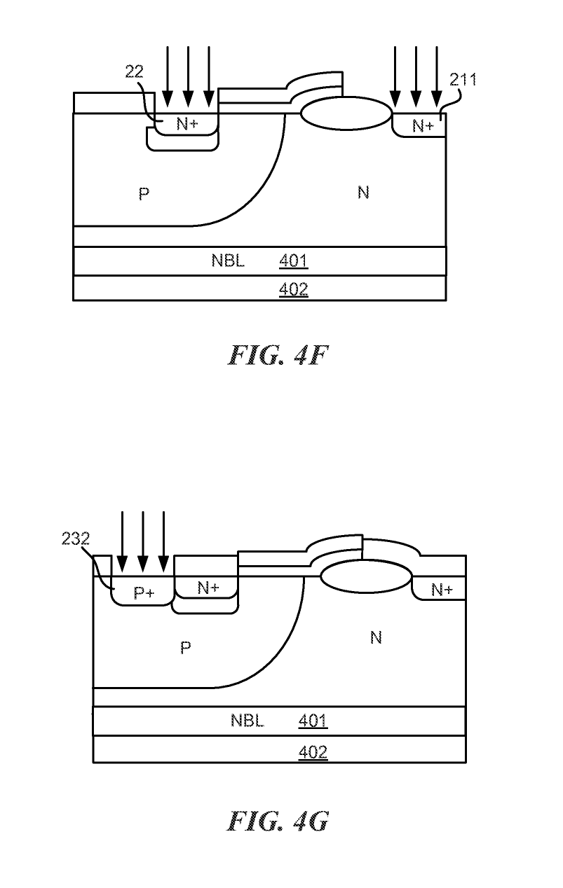

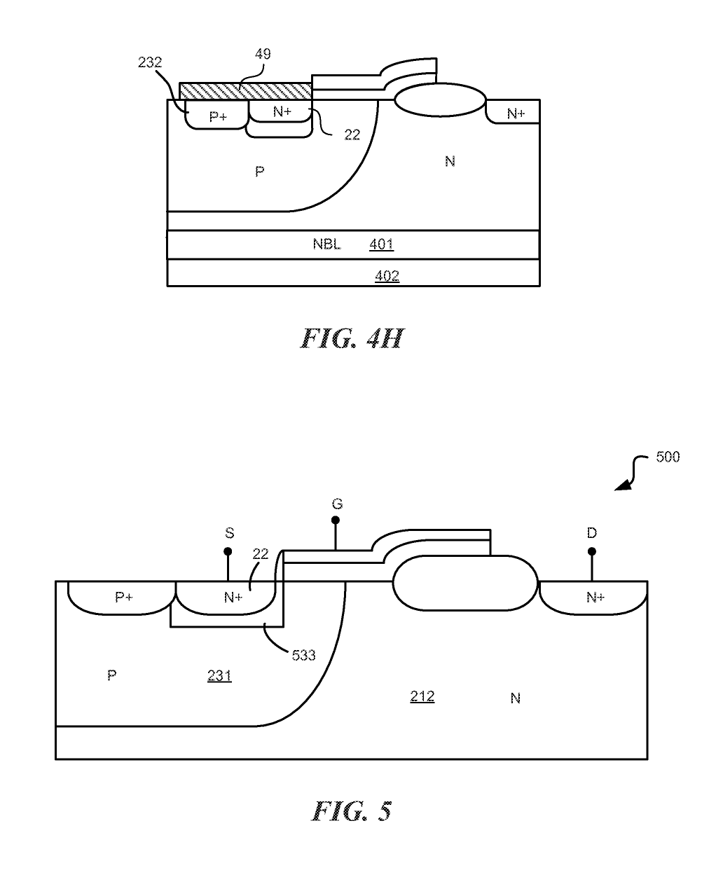

FIGS. 4A-4H illustrate a process flow of fabricating a LDMOS device according to an embodiment of the present invention. The method comprises implanting boron atoms in a semiconductor substrate to form a P-type well for body region of the LDMOS device as illustrated in FIG. 4D and implanting indium atoms into a portion of the P-type well, wherein the indium implanted region 233 is adjacent to and immediately beneath the source region 22 of the LDMOS device as illustrated in FIG. 4E. In another embodiment, the indium atoms may be implanted before implanting the boron atoms.

In FIG. 4A, N-type dopants are implanted in a semiconductor substrate 40 to form an N-type well 41. N-type well 41 is formed by implanting N-type dopants such as phosphorous, arsenic, antimony, or combinations thereof. In one embodiment the total N-type charge in the well 41 could be on the order of 4×10¹² atoms per cm². The semiconductor substrate 40 may comprise an initial substrate 401, an N-type buried layer (NBL) 402 formed on the initial substrate 401, and an epitaxial layer 403 formed on the initial substrate 401 and the NBL layer 402. In one embodiment, the epitaxial layer 403 is also doped with N-type dopants. The initial substrate 401 may either be doped with N-type dopants, P-type dopants, or be intrinsic semiconductor material. However, the semiconductor substrate 40 is not restricted to the exemplary configuration shown in FIG. 4A, and the semiconductor substrate 40 may be in various forms, may have other integrated circuits, devices or systems. Part of N-type well 41 forms the drift region of the target LDMOS device. The drift region may be isolated from the substrate 40 by a combination of N-type and P-type dopants at different depths. In another embodiment, drift region may be formed by directly forming an N-type epitaxial layer on a semiconductor substrate.

In FIG. 4B, a thick oxide 26 is formed on the N-type well 41. The processes as illustrated in FIGS. 4B-4H are taken out only in part of the sectional area in FIG. 4A for ease of illustration, which is denoted as area A. It is noted that in one N-type well 41, a LDMOS device comprising one body region and two gate regions may be formed from the sectional view, or a LDMOS device comprising two or more duplicated regions may be formed.

Continuing with FIG. 4B, thick oxide 26 is a field dielectric region to improve the breakdown voltage of the LDMOS device. In one embodiment, the thick oxide 26 may be formed by oxidizing the surface of the N-type well 41 and then etching off the thick oxide in regions not covered by a masking layer (not shown), In another embodiment, the thick oxide may be eliminated or the LDMOS device may have another structure functioning in a way similar to the thick oxide.

Then in FIG. 4C, the gate 24 is formed at the surface 43 of the semiconductor substrate. To be specific, the gate 24 is formed partially above the thick oxide 26. In one embodiment, forming the gate comprises forming a silicon dioxide layer 241 and then forming a polycrystalline silicon layer 242 on the silicon dioxide layer 241. In one embodiment, after forming the silicon dioxide layer and polycrystalline silicon layer, forming the gate 24 may further comprise patterning the gate by etching via a mask.

In FIG. 4D, boron atoms are implanted into the N-type well 41 to form a P-type well 42 for the body region of the LDMOS device. And thermal annealing step is taken out thereafter to drive the boron atoms laterally diffusing to under the gate 24, to form a channel region of the LDMOS device. Thus a junction between the N-type well 41 and P-type well 42 is created.

In FIG. 4E, indium atoms are implanted into the Pwell 42. The indium atoms are implanted in the region 233 adjacent to and beneath the source region 22 of the LDMOS device, In the shown embodiment, the indium atoms are implanted with zero tilt. However, in another embodiment, the indium atoms with a small implanting tilt may also be in the spirit of the present invention. The energy of indium atoms is selected to be high enough so that the projected range of the indium atoms is close to the ultimate depth of the junction between the source 22 and the body, and the energy of indium atoms is also selected to be low enough so that the polycrystalline silicon layer 242 blocks the indium atoms from penetrating. In one embodiment, the thickness d2 of the P-type well 42 is about 770 nm, and the indium atoms are implanted with a thickness dl of about 100 nm, which is about 0.13 times the thickness d2 of the body region. The concentration of indium atoms at the second portion body region 233 may be selected in the range of 1×10¹⁸ atoms per cm³ to 5×10¹⁸ atoms per cm³, and the doping concentration of boron atoms at the P-type well region 42 may also be selected in the range of 1×10¹⁸ atoms per cm³ to 5×10¹⁸ atoms per cm³. In one embodiment, the concentration of indium atoms at the second portion body region 233 is about 5×10¹⁸ atoms per cm³, and the doping concentration of boron is about 2×10¹⁸ atoms per cm³. However, the above size relationship and doping concentrations are only for illustration and it is noted that the other size relationships and doping concentrations are also in the spirit of the present invention.

In FIG. 4F, N-type dopants are implanted with high doping concentration to form the source region 22 and the drain contact region 211.

And in FIG. 4G, P-type dopants are implanted with high doping concentration to form a body contact region 232.

In one embodiment as shown in FIG. 4H, a conducting layer 49 is further formed above the source region 22 and the body contact region 232 to electrically short the source 22 and the body contact region 232 of the LDMOS device. The conducting layer 49 may be a silicide layer, a conducting via, a metal interconnect, or in any other possible form.

In one embodiment, the N-type well 41 is not implanted into the area of source region, and the P-type well 42 and the P-type well 41 are next to each other. And in one embodiment, the gate region is formed after performing the boron implantation for the body region.

Some other prior art steps such as forming spacers, interconnection and packaging are not shown for ease of illustration. However, embodiments with these prior art steps are also in the spirit of the present invention as illustrated in the appended claims.

The method claims do not intend to confine the process sequences. For example when a method claim comprises a step A and a step B, it claims both the situations that performing B after A, or performing A after B.

In one embodiment, a LDMOS device with reference to the above embodiments is fabricated simultaneously with bipolar junction transistors and complementary MOS transistors in a Bipolar-CMOS-DMOS (BCD) process.

FIG. 5 illustrates a LDMOS device 500 according to an embodiment of the present invention. The difference between the LDMOS device 500 and the LDMOS device 200 shown in FIG. 2 is that the second portion body region 533 of the LDMOS device 500 where indium atoms are implanted extends past the N-type highly doped source region 22 a short distance toward the drain 212. In one embodiment, the implanted indium atoms extend past the source region because the indium atoms are implanted before forming a gate sidewall spacer, and the source region is implanted after forming the spacer.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

I/We claim:

1. A semiconductor device comprising:
a gate region comprising a dielectric layer and a conducting layer;
an N-type drain region comprising a lightly doped drift region and a highly doped drain contact region formed in the drift region, wherein the drain region is at a first side of the gate region;
a P-type body region adjacent to the drain region, the body region comprising a lightly doped first portion body region, a second portion body region adjacent to the first portion body region, and a highly doped body contact region; and
an N-type highly doped source region in the body region, wherein the source region is at a second side of the gate region;
wherein the first portion body region is doped with boron, the second portion body region is doped with boron and indium, and the second portion body region is located adjacent to and beneath the source region,

2. The semiconductor device of claim 1, wherein the second portion body region extends past the N-type highly doped source region a short distance toward the drain.

3. The semiconductor device of claim 1, wherein the second portion body region is self-aligned to the gate region.

4. The semiconductor device of claim 1, wherein the second portion body region is at the junction area of the source region and the body region.

5. The semiconductor device of claim 1, wherein the doping concentration of the indium atoms at the second portion body region is in the range of 1×1018 atoms per cm3 to 5×1018 atoms per cm3, and the doping concentration of the boron atoms at the first portion body region and the second portion body region is also in the range of 1×1018 atoms per cm3 to 5×1018 atoms per cm3.

6. The semiconductor device of claim 1, further comprising:
a drain electrode coupled to the drain contact region; and
a source electrode coupled to the source region and the body contact region.

7. The semiconductor device of claim 1, further comprising a thick oxide formed between the gate region and the drain contact region.

8. A Lateral Diffused Metal-Oxide-Semiconductor Field Effect Transistor (LDMOS) device, comprising a drain, a source, a gate and a body, wherein the body comprises a first portion body region adjacent to and beneath the source, a second portion body region and a body contact region, wherein the first portion body region has dopants of boron and indium, the second portion body region and the body contact region have dopants of boron and no indium, the first portion body region is configured to decrease the resistance between a channel region and the body contact region.

9. The LDMOS device of claim 8, wherein in the first portion body region, the doping concentration of indium is 1 to 3 times the doping concentration of boron.

10. The LDMOS device of claim 9, wherein the thickness of the second portion body region is about 100 nm.

11. A method of fabricating a LDMOS device, the method comprising:
implanting boron atoms in a semiconductor substrate to form a P-type well for the body region of the LDMOS device; and
implanting indium atoms into the P-type well, wherein the indium atoms are implanted adjacent to and beneath a source region of the LDMOS device.

12. The method of claim 11, further comprising forming a gate region of the LDMOS device, wherein the indium atoms are implanted after forming the gate region and the indium atoms are implanted self-aligned to the edge of the gate region.

13. The method of claim 12, wherein the indium atoms are implanted with zero tilt.

14. The method of claim 12, wherein forming the gate region comprises forming a silicon dioxide layer on the semiconductor substrate and forming a polycrystalline silicon layer on the silicon dioxide layer.

15. The method of claim 12, wherein the energy of indium atoms is selected to be high enough so that the projected range of the indium atoms is close to the ultimate depth of the junction between the source region and the body region, and the energy of indium atoms is also selected to be low enough so that the polycrystalline silicon layer blocks the indium atoms from penetrating.

16. The method of claim 11, wherein the indium atoms are implanted with a thickness of about 0.08 to 0.2 times of the thickness of the body region.

17. The method of claim 11, wherein the doping concentration of the indium atoms is in the range of 1×1018 atoms per cm3 to 5×1018 atoms per cm3, and the doping concentration of boron atoms is in the range of 1×1018 atoms per cm3 to 5×1018 atoms per cm3.

18. The method of claim 11, further comprising forming a thick oxide before forming a gate region of the LDMOS device.

19. The method of claim 11, further comprising:
forming an N-type well for a drift region;
forming a gate region at a surface of the semiconductor substrate;
implanting N-type dopants with high doping concentration to form a drain contact region and a source region; and
implanting P-type dopants with high doping concentration to form a body contact region.

20. The method of claim 11, further comprising forming a conducting layer above the source region and the body contact region.
